(19) United States
(12) Patent Application Publication
(10) Pub. No.: US 2026/0065998 A1
(43) Pub. Date: Mar. 5, 2026

(54) SUB-BLOCK ERASE IN MEMORY DEVICES USING SEGMENTED SOURCE PLATES

(71) Applicant: MICRON TECHNOLOGY, INC., Boise, ID (US)

(72) Inventors: Aaron S. Yip, Los Gatos, CA (US); Paolo Tessariol, Arcore (IT); Hong-Yan Chen, San Jose, CA (US); Tomoko Ogura Iwasaki, San Jose, CA (US); Giovanni Maria Paolucci, Milano (IT)

(21) Appl. No.: 19/282,135

(22) Filed: Jul. 28, 2025

Related U.S. Application Data
(60) Provisional application No. 63/687,472, filed on Aug. 27, 2024.

(51) Int. Cl. G11C 16/14; G11C 16/04; G11C 16/08

(52) U.S. Cl. CPC G11C 16/14; G11C 16/0483; G11C 16/08

(57) ABSTRACT

An example memory device includes a memory array and a processing device, operatively coupled to the memory array. The processing device is configured to: receive an erase command identifying a sub-block of a block of the memory array; cause a first voltage level to be applied to a source plate segment associated with the sub-block, thus selecting the sub-block to be erased; cause a second voltage level to be applied to a plurality of source plate segments associated with remaining sub-blocks of the block, such that the first voltage level exceeds the second voltage level by at least a predefined value; and cause a ground voltage level to be applied to one or more data wordlines of the sub-block.

### REFERENCE TO RELATED APPLICATION

This application claims the priority benefit of U.S. Provisional Patent Application No. 63/687,472, filed Aug. 27, 2024, the entirety of which is incorporated herein by reference.

### TECHNICAL FIELD

Implementations of the disclosure relate generally to memory sub-systems, and more specifically, relate to sub-block erase in memory devices using segmented source plates.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various implementations of the disclosure.

FIG. 1A illustrates an example computing system that includes a memory sub-system in accordance with implementations of the present disclosure.

FIG. 1B is a block diagram of a memory device in communication with a memory sub-system controller of a memory sub-system, in accordance with implementations of the present disclosure.

FIG. 2 is a schematic of portions of an array of memory cells as could be used in a memory of the type described with reference to FIG. 1B in accordance with implementations of the present disclosure.

FIG. 3 is a schematic of portions of an array of memory cells implementing non-segregated cells as a drain-side select gates and segmented source plates for sub-blocks in accordance with implementations of the present disclosure.

FIGS. 4A-4B depict block diagrams of portions of an array of memory cells implementing sub-block selection using segmented source plates in accordance with implementations of the present disclosure.

FIGS. 5A-5B schematically illustrate controlling the channel potential at erase-inhibited sub-blocks of an example memory array during a sub-block erase operation, in accordance with implementations of the present disclosure.

FIG. 6 is a flow diagram of an example method of performing sub-block erase operations in accordance with implementations of the present disclosure.

FIG. 7 is a block diagram of an example computer system in which implementations of the present disclosure can operate.

### DETAILED DESCRIPTION

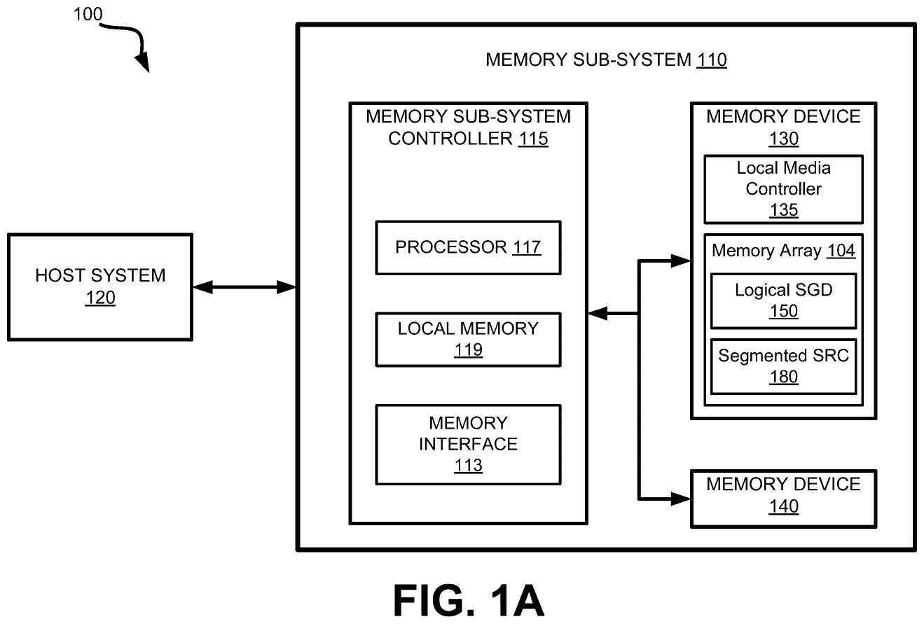

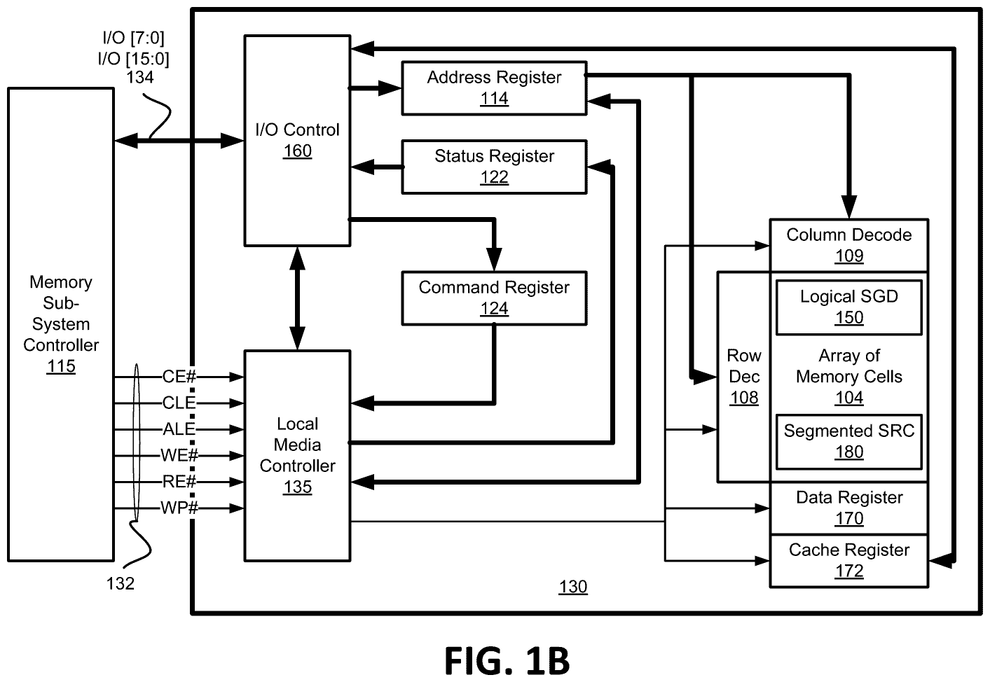

Aspects of the present disclosure are directed to for sub-block erase in a memory device with source conductive lines. A memory sub-system can be a storage device, a memory module, or a hybrid of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, NAND memory, such as 3D flash NAND memory, offers storage in the form of compact, high density configurations. A non-volatile memory device is a package of one or more dice, each including one or more planes. For some types of non-volatile memory devices (e.g., NAND memory), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device (e.g., a memory die) can include memory cells arranged in a two-dimensional or a three-dimensional grid. The memory cells are formed onto a silicon wafer in an array of columns and rows. The memory cells are joined by wordlines, which are conducting lines electrically connected to the control gates of the memory cells, and bitlines, which are conducting lines electrically connected to the drain electrodes of the memory cells. The intersection of a bitline and wordline constitutes the address of the memory cell.

“Block” refers to a unit of the memory device used to store data and can include a set of memory cells addressable by a shared bitline and multiple wordlines of the memory device. Each block can include multiple sub-blocks, such that each sub-block is defined by one or more pillars (e.g., vertical conductive lines) extending between the shared bitline at one end and a source line at the other end.

A memory device may employ select gate switching devices positioned at either or both ends of each pillar to selectively enable the pillar(s) associated with a certain sub-block, while disabling the pillars associated with other sub-blocks, thus allowing separately accessing each sub-block. However, some memory devices utilize a common source plate that is shared by multiple blocks and their respective sub-blocks. Accordingly, a block would be the minimum erasable unit, thus simultaneously erasing all sub-blocks of the selected block.

In an illustrative example, an erase operation would involve pulling up all pillars of the selected block to a predefined high voltage (e.g., ˜25V) through gate-induced drain leakage (GIDL) at the bitline to the pillar junction and at the source plate to the pillar junction of the string, while the wordlines are held to the ground. In some implementations, the drain junction of the string connected to the bitline is equipped with special implants in order to optimize the GIDL current generation that charges up the pillar to the predefined high voltage. Thus, both the source line and the bitlines are driven to the predefined high voltage. The resulting voltage biasing will erase the memory cells of all sub-blocks of the selected block.

Aspects of the present disclosure enable sub-block erase operations in a memory device with segmented source plates. In some implementations, the source plate can be segmented (e.g., by cuts or slits) to produce multiple physically separate source plate segments, each associated with a respective sub-block.

Accordingly, the source plate segment of a chosen sub-block can be driven to the pre-defined high voltage in order to erase the sub-block. However, the remaining sub-blocks will need to be inhibited from being erased, which may involve preventing the channel potential from being driven to the bitline voltage level.

In some implementations, a memory device with segmented source plates can employ virtual select gate switching devices at the drain-side of the sub-blocks (“virtual SGD”), such that each virtual SGD switching device is implemented by the memory cells coupled to a subset of a predefined number of wordlines that are adjacent to the drain side. In an illustrative example, the virtual SGDs can be non-segregated, e.g., coupled to a shared wordline and controlled by the same control signal. Alternatively, virtual SGDs can be physically segregated from each other. The memory cells of the virtual SGDs can be programmed with threshold voltages in a certain pattern such that the application of control signals having specific voltages to the wordlines can selectively activate one of the sub-blocks.

One or more virtual SGD wordlines can be programmed to a predefined threshold voltage (Vt) level, thus reducing the channel potential by approximately the value of the predefined threshold voltage (Vt) level.

The requisite graduate potential change can be further facilitated by inserting a predefined number of drain-side dummy wordlines between the data wordlines and the virtual SGD wordlines. As the memory cells of the drain-side dummy wordlines are unprogrammed, their threshold voltage Vt is assumed to be ˜0V. The gate voltages VG applied to the drain-side dummy wordlines gradually decrease thus brining the channel potential to a chosen level (e.g., ˜0V).

The data wordlines, the highest Vt of the memory cells of which is assumed to be, e.g., ˜4V, further decrease the channel potential to the desired level (e.g., ˜−4V), which inhibits the memory cells of the data wordlines from being erased.

Similarly, on the source side, the channel potential is gradually decreased from the bias voltage V_{SL} that is applied to the source plate segment to the chosen lowest channel potential (e.g., ˜4V). In some implementations, the chosen gate voltage (e.g., ˜7V) applied to the GIDL generator layer causes the channel potential to be brought down to approximately the same level (e.g., ˜7V).

The requisite graduate potential change can be further facilitated by inserting a predefined number of source-side dummy wordlines between the data wordlines and the GIDL generator layer. As the memory cells of the source-side dummy wordlines are unprogrammed, their threshold voltage Vt is assumed to be ˜0V. The gate voltages VG applied to the source-side dummy wordlines gradually decrease by a predefined step value, thus decreasing the channel potential to the chosen level (e.g., ˜0V).

Accordingly, for erasing a sub-block, the controller can selectively drive the source plate segment of a chosen sub-block to be erased to a pre-defined high voltage in order to erase the sub-block, while holding the wordlines to the ground. The remaining sub-blocks can be inhibited from being erased, which involves preventing the channel potential from being driven to the bitline voltage level, as described in more detail herein below.

Therefore, advantages of the disclosed techniques include enabling selective sub-block erase operations, thus improving the overall efficiency of the memory device.

FIG. 1A illustrates an example computing system 100 that includes a memory sub-system 110 in accordance with implementations of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some implementations, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., memory devices 130) when the memory sub-system 110 is coupled with the host system 120 by the PCIe interface. The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include not-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some implementations, each of the memory devices 130 can include one or more arrays of memory cells such as SLCs, MLCs, TLCs, QLCS, or any combination of such. In some implementations, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), not-or (NOR) flash memory, electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some implementations, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another implementation of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some implementations, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some implementations, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some implementations, a memory device 130 is a managed memory device, which is a raw memory device 130 having control logic (e.g., local controller 135) on the die and a controller (e.g., memory sub-system controller 115) for media management within the same memory device package. An example of a managed memory device is a managed NAND (MNAND) device. Memory device 130, for example, can represent a single die having some control logic (e.g., local media controller 135) embodied thereon. In some implementations, one or more components of memory sub-system 110 can be omitted.

In some implementations, memory sub-system 110 includes a memory interface component 113. Memory interface component 113 is responsible for handling interactions of memory sub-system controller 115 with the memory devices of memory sub-system 110, such as memory device 130. For example, memory interface component 113 can send memory access commands corresponding to requests received from host system 120 to memory device 130, such as program commands, read commands, or other commands. In addition, memory interface component 113 can receive data from memory device 130, such as data retrieved in response to a read command or a confirmation that a program command was successfully performed. In some implementations, the memory sub-system controller 115 includes at least a portion of the memory interface 113. For example, the memory sub-system controller 115 can include a processor 117 (e.g., a processing device) configured to execute instructions stored in local memory 119 for performing the operations described herein. In some implementations, the memory interface component 113 is part of the host system 110, an application, or an operating system.

In some implementations, memory device 130 includes local media controller 135 and a memory array 104. As described herein, the memory array 104 can include multiple memory cells organized in multiple blocks of a predefined size, such that each block further includes multiple sub-blocks. In some implementations, each block includes multiple virtual SGD wordlines 150 at a drain-side of the sub-blocks, such that the number of virtual SGD wordlines 150 is greater than or equal to the number of sub-blocks. For example, if a block includes four sub-blocks, there can be four virtual SGD wordlines 150. Similarly, if a block includes eight sub-blocks, there can be eight virtual SGD wordlines 150. In addition, if a block includes three sub-blocks, there could still be four virtual SGD wordlines, for example.

In some implementations, each virtual SGD wordline 150 implements a respective select gate switching device that is formed using core memory cells (e.g., replacement gate transistors with a charge trapping structure). In some implementations, these select gate switching devices are non-segregated, such that all select gate switching devices are coupled to a shared wordline and controlled by the same control signal. Alternatively, virtual SGD wordlines at the drain-side of the sub-blocks can be physically segregated from each other.

In some implementations, the select gate switching devices in the virtual SGD wordlines 150 are programmed with threshold voltages in a certain pattern such that the application of control signals from local media controller 135 having specific voltages on the wordlines can selectively activate a chosen sub-block. For example, each virtual SGD wordline can have half of the select gate switching devices programmed with a high threshold voltage and half of the select gate switching devices programmed with a low threshold voltage, while each sub-block has select gate switching devices in half of the virtual SGD wordlines programmed with the high threshold voltage and select gate switching devices in half of the virtual SGD wordlines programmed with the low threshold voltage.

In some implementations, each block in the memory array 104 can have a segmented source (SRC) plate 180. For example, rather than utilizing a common source plate, the source plate 180 can be segmented (e.g., by cuts or slits) so that each sub-block of the memory array would be associated with a respective separate segment. Depending on the implementation, the number of source segments can be equal to the number of sub-blocks. In some implementations, control logic can apply separate source voltages to the individual source plate segments to selectively activate different sub-blocks for performing programming or erase operations. Further details with regards to the structure and operation of the virtual SGD wordlines 150 and the segmented source plate 180 are described below.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an implementation. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device.

Memory device 130 includes an array of memory cells 104 logically arranged in rows and columns. Memory cells of a logical row are typically connected to the same access line (e.g., a wordline) while memory cells of a logical column are typically selectively connected to the same data line (e.g., a bitline). A single access line may be associated with more than one logical row of memory cells and a single data line may be associated with more than one logical column. Memory cells (not shown in FIG. 1B) of at least a portion of array of memory cells 104 are capable of being programmed to one of at least two target data states. In some implementations, the memory array 104 includes a predefined number of virtual SGD wordlines (logical SGD) 150 at a drain-side of each sub-block in the array 104 and a segmented source (SRC) plate 180 with a separate source segment associated with each sub-block in the array 104.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data may be passed from the cache register 172 to the data register 170 for transfer to the array of memory cells 104; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer of the memory device 130. A page buffer may further include sensing devices (not shown in FIG. 1B) to sense a data state of a memory cell of the array of memory cells 104, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 132 depending upon the nature of the memory device 130. In some implementations, memory device 130 receives command signals (which represent commands), address signals (which represent addresses), and data signals (which represent data) from the memory sub-system controller 115 over a multiplexed input/output (I/O) bus 134 and outputs data to the memory sub-system controller 115 over I/O bus 134.

For example, the commands may be received over input/output (I/O) pins [7:0] of I/O bus 134 at I/O control circuitry 160 and may then be written into command register 124. The addresses may be received over input/output (I/O) pins [7:0] of I/O bus 134 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the array of memory cells 104.

In an implementation, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various implementations.

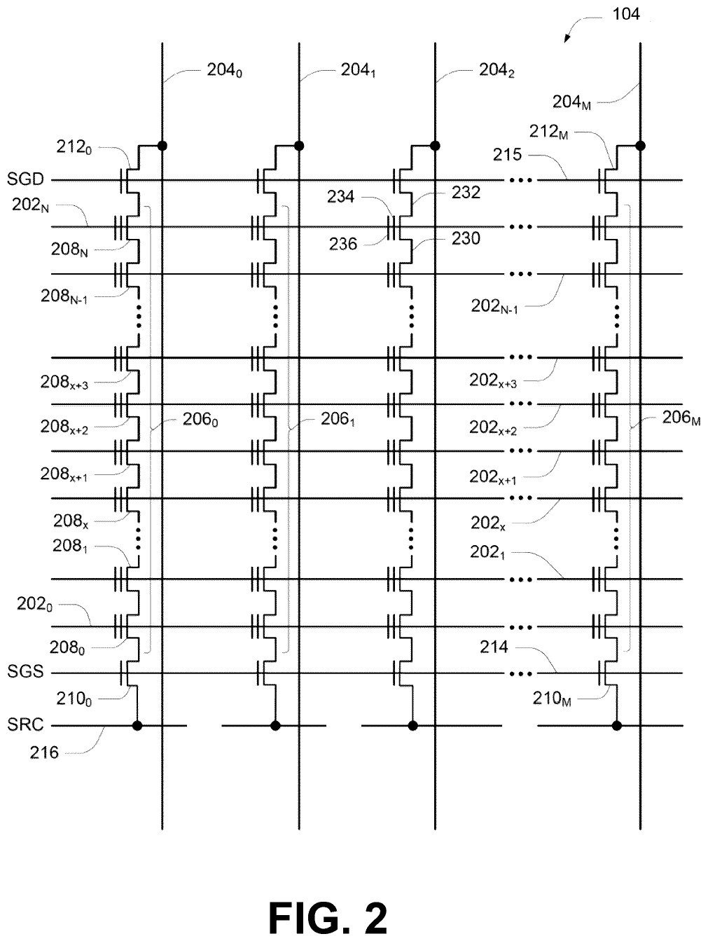

FIG. 2 is a schematic of portions of an array of memory cells 104, such as a NAND memory array, as could be used in a memory of the type described with reference to FIG. 1B according to an implementation. Memory array 104 includes access lines, such as wordlines 202₀ to 202_{N}, and data lines, such as bitlines 204₀ to 204_{M}. The wordlines 202 can be connected to global access lines (e.g., global wordlines), not shown in FIG. 2, in a many-to-one relationship. For some implementations, memory array 104 can be formed over a semiconductor that, for example, can be conductively doped to have a conductivity type, such as a p-type conductivity, e.g., to form a p-well, or an n-type conductivity, e.g., to form an n-well.

Memory array 104 can be arranged in rows (each corresponding to a wordline 202) and columns (each corresponding to a bitline 204). Each column can include a string of series-connected memory cells (e.g., non-volatile memory cells), such as one of NAND strings 206₀ to 206_{M}. Each NAND string 206 can be connected (e.g., selectively connected) to a respective source (SRC) segment (e.g., segment 216) and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal. Although not illustrated in FIG. 2, In some implementations, memory array 104 can include a number of virtual SGD wordlines (i.e., represented by logical SGD 150) at a drain-side of the sub-blocks.

A source of each select gate 210 can be connected to an associated segment of the segmented source plate 180, such as segment 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the respective source segment 216. A control gate of each select gate 210 can be connected to the select line 214.

The drain of each select gate 212 can be connected to the bitline 204 for the corresponding NAND string 206. For example, the drain of select gate 212₀ can be connected to the bitline 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bitline 204. A control gate of each select gate 212 can be connected to select line 215.

The memory array 104 in FIG. 2 can be a quasi-two-dimensional memory array and can have a generally planar structure, e.g., where the source segments 216, NAND strings 206 and bitlines 204 extend in substantially parallel planes. Alternatively, the memory array 104 in FIG. 2 can be a three-dimensional memory array, e.g., where NAND strings 206 can extend substantially perpendicular to a plane containing the source segments 216 and to a plane containing the bitlines 204 that can be substantially parallel to the plane containing the source segments 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bitline 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bitlines 204 (e.g., bitlines 204₀, 204₂, 204₄, etc.) can be one physical page of the memory cells 208 (e.g., even memory cells) while memory cells 208 commonly connected to wordline 202_{N} and selectively connected to odd bitlines 204 (e.g., bitlines 204₁, 204₃, 204₅, etc.) can be another physical page of the memory cells 208 (e.g., odd memory cells).

Although bitlines 204₃-204₅ are not explicitly depicted in FIG. 2, it is apparent from the figure that the bitlines 204 of the array of memory cells 104 can be numbered consecutively from bitline 204₀ to bitline 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some implementations, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2 is discussed in conjunction with NAND flash, the implementations and concepts described herein are not limited to a particular array architecture or structure, and can include other structures (e.g., SONOS, phase change, ferroelectric, etc.) and other architectures (e.g., AND arrays, NOR arrays, etc.).

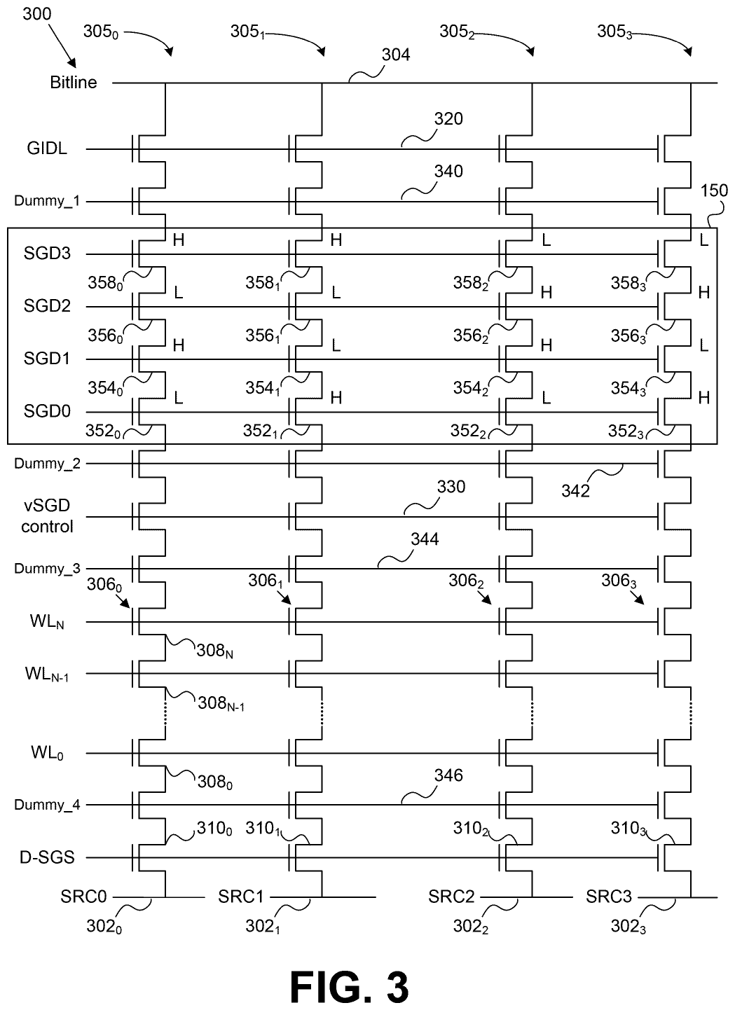

FIG. 3 is a schematic of portions of an array of memory cells implementing non-segregated cells as a drain-side select gates for sub-blocks in accordance with implementations of the present disclosure. The portion of the array of memory cells, such as memory array 104, can be a block 300, for example. In some implementations, the block 300 includes strings of memory cells that can be grouped into sub-blocks, such as sub-blocks 305₀-305₃. Other numbers of sub-blocks can be included in other implementations.

Specifically, in at least some implementations, the block 300 includes a bitline 304, where each sub-block is coupled to the bitline 304 and to respective source (SRC) segment, such as one of segmented source segments 302₀-302₃. The first sub-block 305₀ can include a first string of memory cells 306₀ coupled therebetween. The second sub-block 305₁ can include a second string of memory cells 306₁ coupled therebetween. The third sub-block 305₂ can include a third string of memory cells 306₂ coupled therebetween. The fourth sub-block 305₃ can include a fourth string of memory cells 306₃ coupled therebetween. By way of example, the first string of memory cells 306₀ includes multiple memory cells 308₀ . . . 308_{N}. In at least some implementations, multiple wordlines (WLs) are coupled with gates of memory cells of each string of memory cells 306₀ . . . 306₃. Each sub-block also includes a respective source select (SGS) transistor 310₀-310₃. Each SGS transistor can be connected to a respective source segment, to provide voltage to the sources of the multiple memory cells 308₀ . . . 308_{N}. In some implementations, the source select gate transistors 310₀-310₃ are formed using core memory cells (e.g., replacement gate transistors with a charge trapping structure) and are non-segregated, such that the transistors are each coupled to a shared wordline and controlled by a same control signal (e.g., D-SGS). In some implementations, source select gate transistor 310₀ is coupled to source segment 302₀, which is controlled by a respective control signal SRC0, source select gate transistor 310₁ is coupled to source segment 302₁, which is controlled by a respective control signal SRC1, source select gate transistor 310₂ is coupled to source segment 302₂, which is controlled by a respective control signal SRC2, and source select gate transistor 310₃ is coupled to source segment 302₃, which is controlled by a respective control signal SRC3.

In some implementations, block 300 includes one or more drain-side gate-induced drain leakage (GIDL) generator devices 320 associated with respective sub-blocks 305₀-305₃ and coupled to bitline 304. The GIDL generator devices in each layer can be connected to a common gate line GIDL, for example.

In some implementations, block 300 includes a predefined number of virtual SGD wordlines 150 including select gate switching devices associated with respective sub-blocks 305₀-305₃. The number of virtual SGD wordlines 150 can be greater than or equal to the number of sub-blocks 305₀-305₃. In some implementations, the select gate switching devices in each of the virtual SGD wordlines 150 are formed using core memory cells (e.g., replacement gate transistors with a charge trapping structure) and are non-segregated, such that devices in each layer are each coupled to a shared wordline and controlled by a same respective control signal (e.g., SGD0, SGD1, SGD2, SGD3).

In some implementations, block 300 includes one or more logical select gate control layers 330 having one or more select gate switching devices associated with respective sub-blocks 305₀-305₃. The select gate switching devices in each layer can be connected to a common gate line vSGD control, for example. The logical select gate control layer 330 can be located further from the drain-side edge of the block 300 than the virtual SGD wordlines and can include select gate switching devices with more finely tuned threshold voltages that the select gate switching devices in the virtual SGD wordlines, which can be more coarsely programmed. In certain implementations, there can be more than one logical select gate control layer in block 300. In addition, the logical select gate control layer(s) could instead be positioned directly above strings of memory cells 306₀ . . . 306₃ or there could be additional logical select gate control layers positioned directly above strings of memory cells 306₀ . . . 306₃ (e.g., below dummy wordline Dummy_3 344).

In some implementations, block 300 includes a predefined number of dummy wordlines located between other layers. For example, dummy wordline Dummy_1 340 can be located between drain-side GIDL generator layer 320 and virtual SGD wordlines 150, dummy wordline Dummy_2 342 can be located between virtual SGD wordlines 150 and logical select gate control layer 330, dummy wordline Dummy_3 344 can be located between logical select gate control layer 330 and strings of memory cells 306₀ . . . 306₃, and dummy wordline Dummy_4 346 can be located between strings of memory cells 306₀ . . . 306₃ and source select transistors 310₀-310₃. Each dummy wordline can include memory cells associated with respective sub-blocks 305₀-305₃, but these memory cells are generally not used for storing data. Depending on the implementation, there can be more than one dummy wordline at the positions of Dummy_1 340, Dummy_2 342, Dummy_3 344, and/or Dummy_4 346.

In some implementations, the select gate switching devices in the virtual SGD wordlines 150 are programmed with threshold voltages in a certain pattern such that the application of control signals (e.g., SGD0, SGD1, SGD2, SGD3) from local media controller 135 having specific voltages on the wordlines can selectively activate one of the sub-blocks 305₀-305₃ at a time. In some implementations, each of virtual SGD wordlines 150 can have half of the select gate switching devices programmed with a high threshold voltage and half of the select gate switching devices programmed with a low threshold voltage, while each of sub-blocks 305₀-305₃ has select gate switching devices in half of the virtual SGD wordlines 150 programmed with the high threshold voltage and select gate switching devices in half of the virtual SGD wordlines 150 programmed with the low threshold voltage. One example pattern is illustrated in block 300 of FIG. 3, however, other patterns are possible.

As illustrated, one layer of virtual SGD wordlines 150 (i.e., the layer controlled by SGD0) includes select gate switching devices 352₀-352₃, where each device is associated with one of sub-blocks 305₀-305₃. In this implementation, select gate switching devices 352₁ and 352₃ are programmed with the high (H) threshold voltage (e.g., 7V) and select gate switching devices 352₀ and 352₂ are programmed with the low (L) threshold voltage (e.g., 3V). In other implementations, the high and low threshold voltages can have different values. Another layer of virtual SGD wordlines 150 (i.e., the layer controlled by SGD1) includes select gate switching devices 354₀-354₃, where each device is associated with one of sub-blocks 305₀-305₃. In this implementation, select gate switching devices 354₀ and 354₂ are programmed with the high (H) threshold voltage (e.g., 7V) and select gate switching devices 354₁ and 354₃ are programmed with the low (L) threshold voltage (e.g., 3V). Another layer of virtual SGD wordlines 150 (i.e., the layer controlled by SGD2) includes select gate switching devices 356₀-356₃, where each device is associated with one of sub-blocks 305₀-305₃. In this implementation, select gate switching devices 356₂ and 356₃ are programmed with the high (H) threshold voltage (e.g., 7V) and select gate switching devices 356₀ and 356₁ are programmed with the low (L) threshold voltage (e.g., 3V). Another layer of virtual SGD wordlines 150 (i.e., the layer controlled by SGD3) includes select gate switching devices 358₀-358₃, where each device is associated with one of sub-blocks 305₀-305₃. In this implementation, select gate switching devices 358₀ and 358₁ are programmed with the high (H) threshold voltage (e.g., 7V) and select gate switching devices 358₂ and 358₃ are programmed with the low (L) threshold voltage (e.g., 3V). Accordingly, sub-block 305₀ includes select gate switching devices 354₀ and 358₀ programmed with the high threshold voltage and select gate switching devices 352₀ and 356₀ programmed with the low threshold voltage. Sub-block 305₁ includes select gate switching devices 352₁ and 358₁ programmed with the high threshold voltage and select gate switching devices 354₁ and 356₁ programmed with the low threshold voltage. Sub-block 305₂ includes select gate switching devices 354₂ and 356₂ programmed with the high threshold voltage and select gate switching devices 351₂ and 358₂ programmed with the low threshold voltage. Sub-block 305₃ includes select gate switching devices 3523 and 356₃ programmed with the high threshold voltage and select gate switching devices 354₃ and 358₃ programmed with the low threshold voltage.

When the threshold voltages of the select gate switching devices in virtual SGD wordlines 150 are programmed in this or a similar pattern, the application of control signals (e.g., SGD0, SGD1, SGD2, SGD3) from local media controller 135 can selectively activate one of the sub-blocks 305₀-305₃ at a time. Table 1 illustrates one example of the control signals that can be applied to the wordlines of virtual SGD wordlines 150 in order to activate each specific sub-block.

TABLE 1

| SGD3 | SGD2 | SGD1 | SGD0 | Activated Sub-block |
|---|---|---|---|---|
| 7 V | 3 V | 7 V | 3 V | 305₀ |
| 7 V | 3 V | 3 V | 7 V | 305₁ |
| 3 V | 7 V | 7 V | 3 V | 305₂ |
| 3 V | 7 V | 3 V | 7 V | 305₃ |

In general, if the control signal applied to a certain wordline has a high voltage (e.g., 7V) then all select gate switching devices on that wordline with a threshold voltage at or below the high voltage will turn on. Similarly, if the control signal has a low voltage (e.g., 3 V) then only the select gate switching devices on that wordline with a threshold voltage at the low voltage will turn on, while those select gate switching devices with a high threshold voltage will remain turned off. By way of example, if it is desired to activate sub-block 305₀ while sub-blocks 305₁-305₃ remain deactivated, the following set of control signals can be applied to the wordlines of virtual SGD wordlines 150. A high voltage is applied at SGD3 causing select gate switching device 358₀ having a high threshold voltage to turn on, a low voltage is applied at SGD2 causing select gate switching device 356₀ having a low threshold voltage to turn on, a high voltage is applied at SGD1 causing select gate switching device 354₀ having a high threshold voltage to turn on, and a low voltage is applied at SGD0 causing select gate switching device 352₀ having a low threshold voltage to turn on. Thus, all of the select gate switching devices in sub-block 305₀ are activated. At the same time, however, the low voltage at SGD0 causes select gate switching device 352₁ having a high threshold voltage to remain off, thereby deactivating sub-block 305₁, the low voltage at SGD2 causes select gate switching device 356₂ having a high threshold voltage to remain off, thereby deactivating sub-block 305₂, and the low voltage at SGD0 causes select gate switching device 3523 having a high threshold voltage to remain off, thereby deactivating sub-block 305₃. Similarly, the other sets of control signals can be applied to the wordlines of virtual SGD wordlines 150 to activate the other sub-blocks.

As described above, the select gate switching devices in virtual SGD wordlines 150 can be formed using core memory cells, such as replacement gate transistors with a charge trapping structure, and thus, have programmable threshold voltages. In some implementations, the select gate switching devices are programmed with a specific threshold voltage pattern by applying certain voltage signals SRC0-SRC3 to the respective source segments 302₀-302₃. For example, to program select gate switching device 358₀ (e.g., to a high threshold voltage), local media controller 135 can cause a control signal D-SGS (e.g., having a magnitude of the supply voltage Vcc) to be applied at the gate of the first SGS transistor 310₀ in sub-block 305₀ to activate the first SGS transistor 310₀ and allow a voltage from the source segment 302₀ (e.g., a ground voltage provided by source control signal SRC0) to fill the channel of sub-block 305₀. The remaining SGS transistors 310₁-310₃ will also be activated by the control signal D-SGS, however, the respective source segments 302₁-302₃ can be driven to the supply voltage Vcc by control signals SRC1-SRC3 thereby causing the channels of sub-blocks 305₁-305₃ to be floating (e.g., up to 10V). Local media controller 135 can further cause a program voltage pulse (e.g., 20V) to be applied to the gate of select gate switching device 358₀ via control signal SGD3. The gate-channel potential difference at select gate switching device 358₀ will be large enough to program select gate switching device 358₀ while the other memory devices in the same virtual SGD wordline, but associated with different sub-blocks, are not programmed. Depending on the implementation, a number of program pulses can be applied in order to bring the select gate switching device 358₀ to a desired threshold voltage level (e.g., 7V). A similar process can be repeated for the remaining select gate switching devices in sub-block 305₀ (i.e., select gate switching devices 356₀, 354₀, 352₀) while the first source segment 302₀ remains at the supply voltage. Once complete, local media controller 135 can move on to sub-block 305₁, drive the source segment 302₁ with the ground voltage while the other source segments 302₀, 302₂, and 303₃ are driven to the supply voltage, and proceed similarly. Once all of the select gate transistors in virtual SGD wordlines 150 have been programmed to the appropriate pattern of threshold voltages, local media controller 135 can similarly program the devices in logical select gate control layer 330, and the memory cells on wordlines WL₀-WL_{N}.

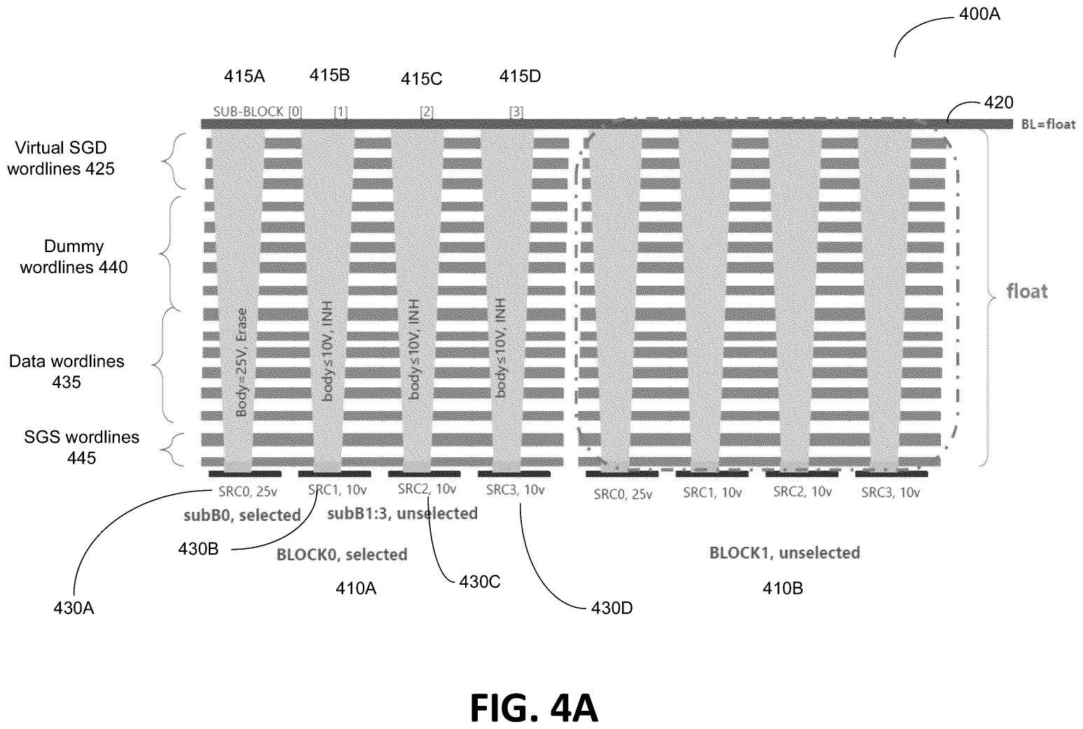

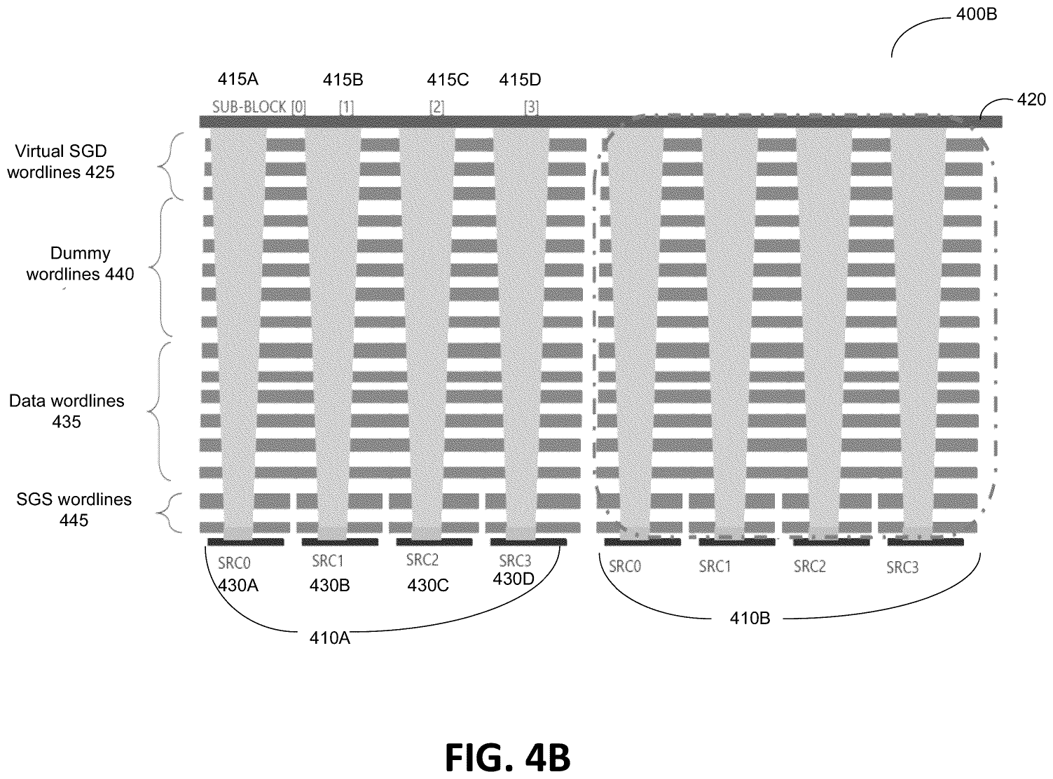

FIG. 4A is a block diagram of portions of an array of memory cells implementing sub-block selection using segmented source plates in accordance with implementations of the present disclosure. The illustrated array portion 400 shows two adjacent blocks 410A and 410B (i.e., Block0 and Block 1) each including respective set of four sub-blocks (i.e., SB0-SB3). As illustrated, block 410A includes the sub-blocks 415A-415D. Each of blocks 410A-410B can be represented by block 300 of FIG. 3.

As further illustrated, the adjacent blocks can share a common bitline 420, and can each have respective set of wordlines that form memory cells as the corresponding intersections with the pillars of each sub-block. In some implementations, the memory cells associated with some number of the wordlines (e.g., those adjacent to the common bitline) in each block can serve as the virtual SGD wordlines 425 to selectively control access to the corresponding sub-blocks in each block. In addition, each block can include a respective set of segmented source plates SRC0-SRC3 that are associated with respective sub-blocks 415A-415D and are physically segregated from each other. For example, each of sub-blocks 415A-415D of block 410A has a respective source segment 430A-430D. As illustrated the source segments can be physically segregated, such as by a cut or slice formed during the processing steps when each of Block0 and Block 1 are formed. Accordingly, each source segment is electronically separate and can be controlled by a respective source control signal (i.e. SRC0-SRC3). Thus, depending on the operations being performed on Block0 and Block1, different source control signals can be applied to the source segments associated with different sub-blocks within either Block0 or Block1.

In some implementations, each block 410 includes a predefined number of additional dummy wordlines 440 located between the virtual SGD wordlines 425 and data wordlines 435, as described in more detail herein below.

In some implementations, each block 410 further includes a predefined number of SGS wordlines 445, the memory cells of which implement the source select gate transistors 310₀-310₃ of FIG. 3. In the illustrative example of FIG. 4A, the source select gate transistors (not shown in FIG. 4A) that are formed using core memory cells of the SGS wordlines 445 are non-segregated, such that all transistors are coupled to a shared wordline and controlled by the same control signal. Conversely, in the illustrative example of FIG. 4B, the source select gate transistors (not shown in FIG. 4B) that are formed using core memory cells of the SGS wordlines 445 are physically segregated, such that each transistor is controlled by a respective dedicated control signal. In some implementations, the source select gate transistor of each sub-block 415A-415D is coupled to the respective source segment 430A-430D.

In some implementations, each of the source segments of a given block, such as source segments 430A-430D of block 410A, is electrically connected to one or more corresponding source segments in several other blocks in the array of memory cells. For example, the source segment associated with SB0 in Block0 is connected to the source segment associated with SB0 in Block1, as well as to the source segment associated with SB0 in several other blocks (not shown). Similarly, the source segments associated with SB1-SB3 in Block0 are connected to the source segments associated with the corresponding SB1-SB3 in Block 1, as well as to the source segments associated with SB1-SB3 in several other blocks (not shown).

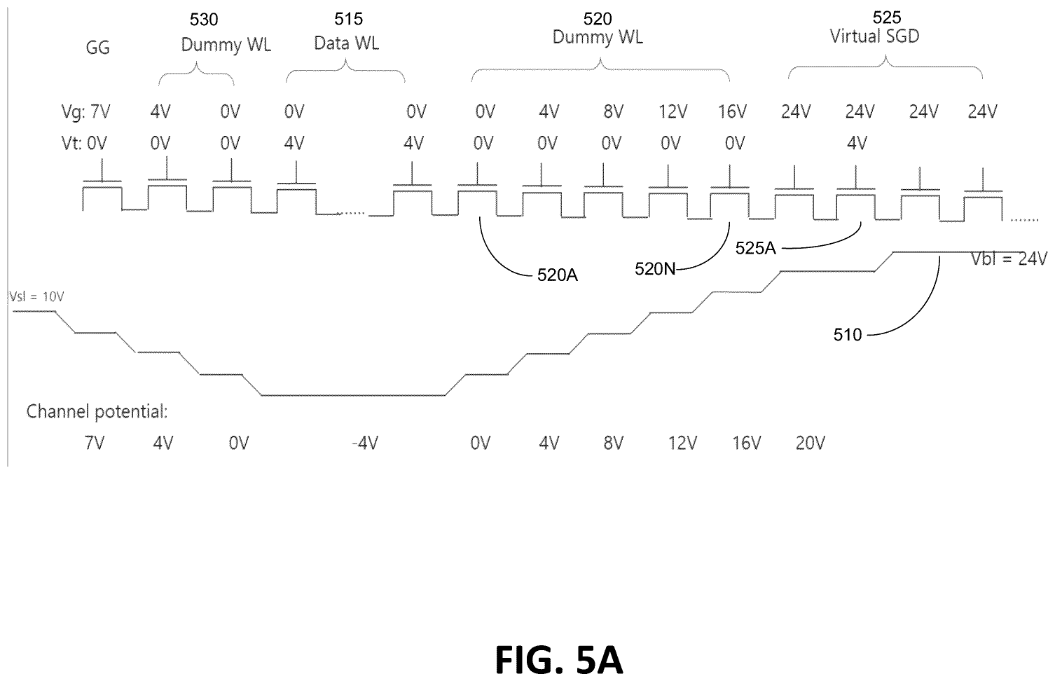

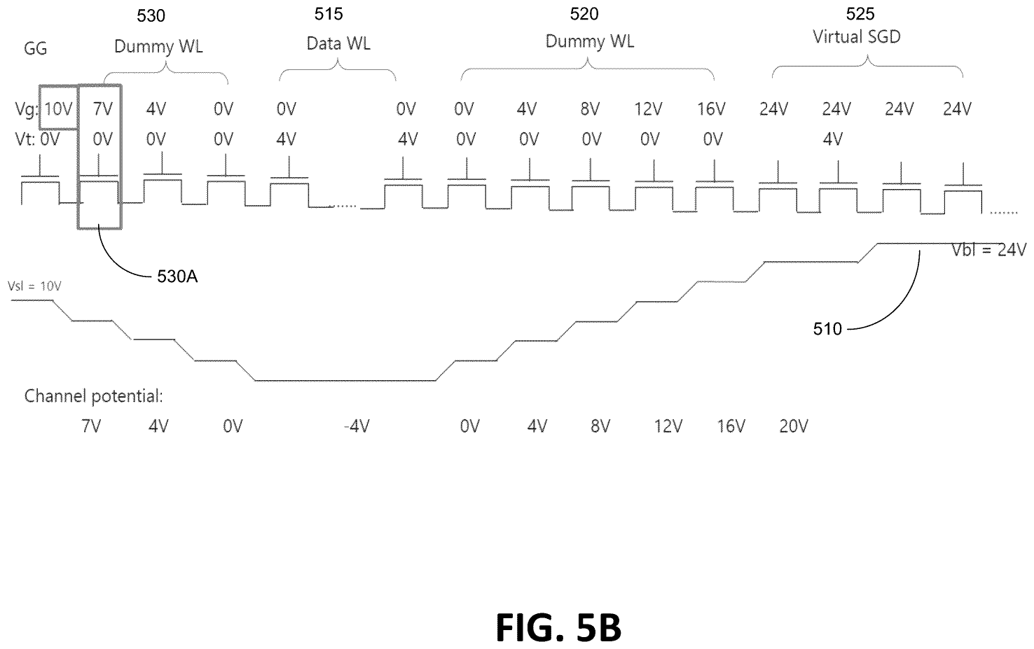

FIGS. 5A-5B schematically illustrate controlling the channel potential at erase-inhibited sub-blocks of an example memory array during a sub-block erase operation, in accordance with implementations of the present disclosure. Physical separation of the source plates enables applying smaller bias voltage V_{SL} (e.g., ˜10V) to the source plate segments corresponding to erase-inhibited sub-blocks (i.e., a sub-block that is not being erased, for example, sub-block 410B of FIGS. 4A-4B), as compared to the higher voltage (e.g., ˜24V) that need to be applied to the source plate segments of the sub-blocks to be erased (e.g., sub-block 410A of FIGS. 4A-4B).

In order to ensure that the channel potential 510 would not be brought to the bitline voltage level V_{BL}. (e.g., ˜24V), a graduate potential change needs to be implemented for the channel of the erase-inhibited sub-blocks, such that a safe voltage level (e.g., ˜4V) would be maintained for the data wordlines 515 of the erase-inhibited sub-blocks.

On the drain side, one or more virtual SGD wordline(s) 525A are randomly chosen among all virtual SGD wordlines 525, and memory cells of the chosen SGD wordline(s) 525A are programmed to a predefined threshold voltage (Vt) level (e.g., ˜4V), thus reducing the channel potential by approximately the value of the predefined threshold voltage (Vt) level 530 (e.g., ˜4V). The same gate voltage (Vg) (e.g., ˜24V) is applied to the gates of all virtual SGD wordlines 525.

In some implementations, the requisite graduate potential change can be further facilitated by inserting a predefined number of drain-side dummy wordlines 520 between the data wordlines 515 and the virtual SGD wordlines 525. As the memory cells of the drain-side dummy wordlines 520 are unprogrammed, their threshold voltage Vt is assumed to be ˜0V. The gate voltages VG applied to the drain-side dummy wordlines 520 gradually decrease from, e.g., ˜16V at the dummy wordline 520N that is closes to the drain side to, e.g., ˜0V at the dummy wordline 520A that is closes to the data wordlines 515, thus decreasing the channel potential to ˜0V. As each drain-side dummy wordline 520 reduces the channel potential by the chosen voltage decrement value, the number of drain-side dummy wordlines 520 can be calculated to decrease the channel potential to a desired level (e.g., 0V in the illustrative example of FIG. 5A).

The data wordlines 515 are assumed to be programmed to store a random data pattern. Therefore, the highest Vt of the memory cells of the data wordlines 515 is assumed to be, e.g., ˜4V, thus further decreasing the channel potential to, e.g., ˜-4V, which inhibits the memory cells of the data wordlines 515 from being erased.

Similarly, on the source side, the channel potential is gradually decreased from the bias voltage V_{SL} (e.g., ˜10V) that is applied to the source plate segment to the chosen lowest channel potential (e.g., ˜4V). In the illustrative example of FIG. 5A, the chosen gate voltage (e.g., ˜7V) applied to GIDL generator layer 535 causes the channel potential to be brought down to approximately the same level (e.g., ˜7V).

In some implementations, the requisite graduate potential change can be further facilitated by inserting a predefined number of source-side dummy wordlines 530 between the data wordlines 515 and the GIDL generator layer 535. As the memory cells of the source-side dummy wordlines 530 are unprogrammed, their threshold voltage Vt is assumed to be ˜0V. The gate voltages VG applied to the source-side dummy wordlines 530 gradually decrease by a predefined step value, thus decreasing the channel potential to a chosen level (e.g., ˜0V). As each source-side dummy wordline 530 reduces the channel potential by the chosen voltage decrement value, the number of source-side dummy wordlines 530 can be calculated to decrease the channel potential to a desired level (e.g., ˜0V in the illustrative example of FIG. 5A).

Conversely, in the illustrative example of FIG. 5B, the gate voltage applied to GIDL generator layer 535 is approximately the same as the bias voltage V_{SL} (e.g., ˜10V) that is applied to the source plate segment, and thus an additional source-side dummy wordline is needed, as compared to the example of FIG. 5A, in order to bring the channel potential to the desired value (e.g., ˜−4V).

Furthermore, a higher voltage (e.g., ˜24V) needs to be applied to the source plate segments of the sub-blocks to be erased (e.g., sub-block 410A of FIGS. 4A-4B), which would lead approximately same potential (e.g., ˜24V) of the channel, thus erasing all the memory cells of the selected sub-block 410A.

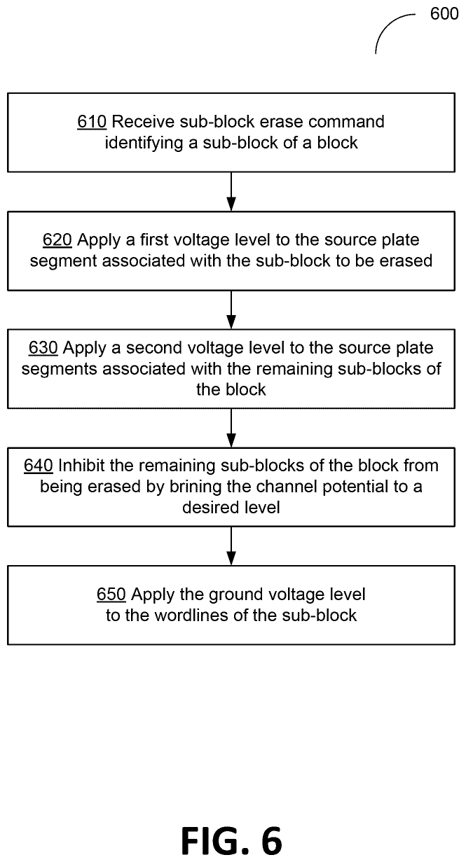

FIG. 6 is a flow diagram of an example method of performing sub-block erase operations in accordance with implementations of the present disclosure. The method 600 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some implementations, the method 600 is performed by local media controller 135 of FIG. 1A and FIG. 1B. Although shown in a particular sequence or order, unless otherwise specified, the order of the processes can be modified. Thus, the illustrated implementations should be understood only as examples, and the illustrated processes can be performed in a different order, and some processes can be performed in parallel. Additionally, one or more processes can be omitted in various implementations. Thus, not all processes are required in every implementation. Other process flows are possible.

At operation 610, the processing device implementing the method receives a sub-block erase command identifying a sub-block of a block of a memory array.

At operation 620, the processing device causes a first voltage level to be applied to a source plate segment associated with the sub-block, thus selecting the sub-block to be erased, as described in more detail herein above.

At operation 630, the processing device causes a second voltage level to be applied to a plurality of source plate segments associated with remaining sub-blocks of the block. The first voltage level can exceed the second voltage level by at least a predefined value, as described in more detail herein above.

At operation 640, the processing device inhibits the remaining sub-blocks of the block from being erased by causing a channel potential of each of the remaining sub-blocks to be brought to a predefined voltage level, as described in more detail herein above.

In some implementations inhibits the remaining sub-blocks of the block from being erased further involves causing a third voltage level to be applied to a plurality of virtual SGD wordlines of the sub-block, as described in more detail herein above.

In some implementations inhibiting the remaining sub-blocks of the block from being erased further involves causing a plurality of fourth voltage levels to be applied to respective drain-side dummy wordlines of the remaining sub-blocks of the block, such that the lowest voltage level is applied to the drain-side dummy wordline that is adjacent to a data wordline. The number of the drain-side dummy wordlines of each remaining sub-block can be calculated to bring the channel potential of the sub-block to a desired level.

In some implementations inhibiting the remaining sub-blocks of the block from being erased further involves causing a plurality of fifth voltage levels to be applied to respective source-side dummy wordlines of the remaining sub-blocks of the block, such that the lowest voltage level is applied to the source-side dummy wordline that is adjacent to a data wordline. The number of the source-side dummy wordlines of each remaining sub-block can be calculated to bring the channel potential of the sub-block to a desired value.

At operation 650, the processing device causes a ground voltage level to be applied to one or more data wordlines of the sub-block, as described in more detail herein above.

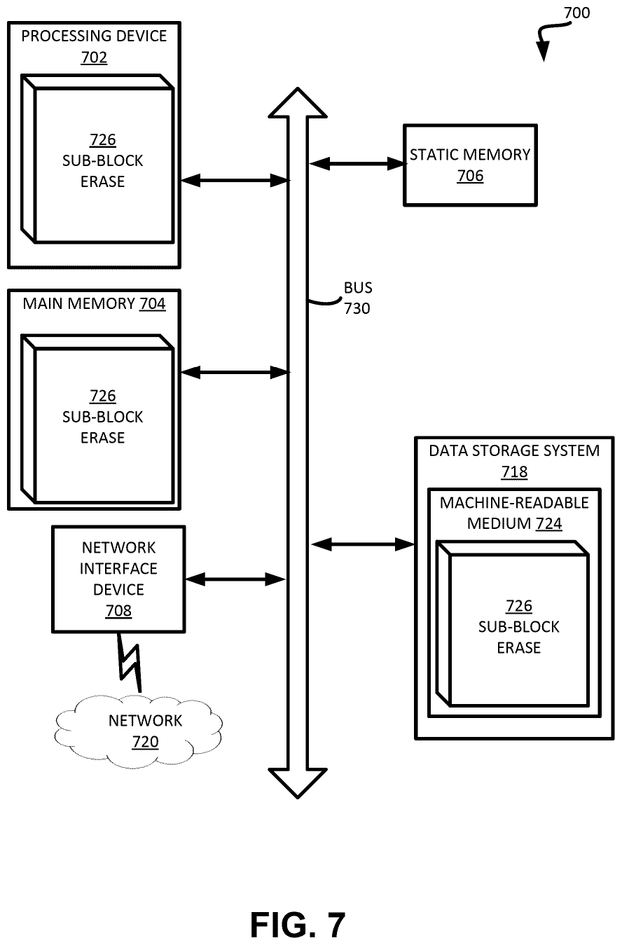

FIG. 7 illustrates an example machine of a computer system 700 within which a set of instructions, for causing the machine to perform any one or more of the methodologies discussed herein, can be executed. In some implementations, the computer system 700 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the local media controller 135 of FIG. 1). In alternative implementations, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 700 includes a processing device 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a data storage system 718, which communicate with each other via a bus 730.

Processing device 702 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 702 can also be one or more special-purpose processing devices such as an application specific integrated circuit (ASIC), a field programmable gate array (FPGA), a digital signal processor (DSP), network processor, or the like. The processing device 702 is configured to execute instructions 726 for performing the sub-block erase operations in accordance with implementations of the present disclosure. The computer system 700 can further include a network interface device 708 to communicate over the network 720.

The data storage system 718 can include a machine-readable storage medium 724 (also known as a computer-readable medium) on which is stored one or more sets of instructions 726 or software embodying any one or more of the methodologies or functions described herein. The instructions 726 can also reside, completely or at least partially, within the main memory 704 and/or within the processing device 702 during execution thereof by the computer system 700, the main memory 704 and the processing device 702 also constituting machine-readable storage media. The machine-readable storage medium 724, data storage system 718, and/or main memory 704 can correspond to the memory sub-system 110 of FIG. 1.

In some implementations, the instructions 726 include instructions to implement functionality corresponding to the local media controller 135 of FIG. 1, including performing the sub-block erase operations in accordance with implementations of the present disclosure. While the machine-readable storage medium 724 is shown in an example implementation to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some implementations, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, implementations of the disclosure have been described with reference to specific example implementations thereof. It will be evident that various modifications can be made thereto without departing from the broader spirit and scope of implementations of the disclosure as set forth in the following claims. The specification and drawings are, accordingly, to be regarded in an illustrative sense rather than a restrictive sense.

What is claimed is:

1. A memory device comprising:
a memory array;
a processing device, operatively coupled to the memory array, the processing device configured to:
receive an erase command identifying a sub-block of a block of the memory array;
cause a first voltage level to be applied to a source plate segment associated with the sub-block, thus selecting the sub-block to be erased;
cause a second voltage level to be applied to a plurality of source plate segments associated with remaining sub-blocks of the block, wherein the first voltage level exceeds the second voltage level by at least a predefined value; and
cause a ground voltage level to be applied to one or more data wordlines of the sub-block.

2. The memory device of claim 1, wherein the processing device is further configured to:
inhibit remaining sub-blocks of the block from being erased by causing a channel potential of each of the remaining sub-blocks to be brought to a predefined voltage level.

3. The memory device of claim 1, wherein the processing device is further configured to:
cause a third voltage level to be applied to a plurality of virtual SGD wordlines of the sub-block.

4. The memory device of claim 1, wherein the processing device is further configured to:
cause a plurality of fourth voltage levels to be applied to respective drain-side dummy wordlines of the remaining sub-blocks of the block.

5. The memory device of claim 3, wherein a lowest voltage level is applied to a drain-side dummy wordline that is adjacent to a data wordline.

6. The memory device of claim 3, wherein a number of the drain-side dummy wordlines of each remaining sub-block is calculated to bring a channel potential of the sub-block to a desired level.

7. The memory device of claim 1, wherein the processing device is further configured to:
cause a plurality of fifth voltage levels to be applied to respective source-side dummy wordlines of the remaining sub-blocks of the block.

8. The memory device of claim 6, wherein a lowest voltage level is applied to a source-side dummy wordline that is adjacent to a data wordline.

9. The memory device of claim 6, wherein a number of the source-side dummy wordlines of each remaining sub-block is calculated to bring a channel potential of the sub-block to a desired level.

10. A method, comprising:
receiving, by a processing device, an erase command identifying a sub-block of a block of the memory array;
causing a first voltage level to be applied to a source plate segment associated with the sub-block, thus selecting the sub-block to be erased;
causing a second voltage level to be applied to a plurality of source plate segments associated with remaining sub-blocks of the block, wherein the first voltage level exceeds the second voltage level by at least a predefined value; and
causing a ground voltage level to be applied to one or more data wordlines of the sub-block.

11. The method of claim 10, further comprising:
inhibiting remaining sub-blocks of the block from being erased by causing a channel potential of each of the remaining sub-blocks to be brought to a predefined voltage level.

12. The method of claim 10, further comprising:
causing a third voltage level to be applied to a plurality of virtual SGD wordlines of the sub-block.

13. The method of claim 10, further comprising:
causing a plurality of fourth voltage levels to be applied to respective drain-side dummy wordlines of the remaining sub-blocks of the block, wherein a lowest voltage level is applied to a drain-side dummy wordline that is adjacent to a data wordline.

14. The method of claim 1, further comprising:
causing a plurality of fifth voltage levels to be applied to respective source-side dummy wordlines of the remaining sub-blocks of the block, wherein a lowest voltage level is applied to a source-side dummy wordline that is adjacent to a data wordline.

15. A non-transitory computer readable storage medium comprising executable instructions that, when executed by a processing device, cause the processing device to:
receive an erase command identifying a sub-block of a block of the memory array;
cause a first voltage level to be applied to a source plate segment associated with the sub-block, thus selecting the sub-block to be erased;
cause a second voltage level to be applied to a plurality of source plate segments associated with remaining sub-blocks of the block, wherein the first voltage level exceeds the second voltage level by at least a predefined value; and
cause a ground voltage level to be applied to one or more data wordlines of the sub-block.

16. The non-transitory computer readable storage medium of claim 15, further comprising executable instructions that, when executed by the processing device, cause the processing device to:
inhibit remaining sub-blocks of the block from being erased by causing a channel potential of each of the remaining sub-blocks to be brought to a predefined voltage level.

17. The non-transitory computer readable storage medium of claim 15, further comprising executable instructions that, when executed by the processing device, cause the processing device to:
cause a third voltage level to be applied to a plurality of virtual SGD wordlines of the sub-block.

18. The non-transitory computer readable storage medium of claim 15, further comprising executable instructions that, when executed by the processing device, cause the processing device to:
cause a plurality of fourth voltage levels to be applied to respective drain-side dummy wordlines of the remaining sub-blocks of the block, wherein a lowest voltage level is applied to a drain-side dummy wordline that is adjacent to a data wordline.

19. The non-transitory computer readable storage medium of claim 1, further comprising executable instructions that, when executed by the processing device, cause the processing device to:
cause a plurality of fifth voltage levels to be applied to respective source-side dummy wordlines of the remaining sub-blocks of the block, wherein a lowest voltage level is applied to a source-side dummy wordline that is adjacent to a data wordline.

20. The non-transitory computer readable storage medium of claim 19, wherein a number of the source-side dummy wordlines of each remaining sub-block is calculated to bring a channel potential of the sub-block to a desired level.
